(19) United States
(12) Patent Application Publication
(10) Pub. No.: US 2012/0074998 A1
(43) Pub. Date: Mar. 29, 2012

(54) INTEGRATED CIRCUIT DEVICE, ELECTRONIC DEVICE AND METHOD FOR COMPENSATING FREQUENCY DRIFT OF A CONTROLLABLE OSCILLATOR

(76) Inventors: Stephen Jonathan Brett, East Malling (GB); Augusto Marques, Moscavide (PT); Jonathan Richard STRANGE, Reigate (GB)

(21) Appl. No.: 13/115,126

(22) Filed: May 25, 2011

Related U.S. Application Data
(60) Provisional application No. 61/386,885, filed on Sep. 27, 2010.

(51) Int. Cl. H03L 7/08

(52) U.S. Cl. 327/157

(57) ABSTRACT

An integrated circuit device for compensating frequency drift of a controllable oscillator is described. The integrated circuit device includes at least one compensation module including: an input for receiving at least an indication of a frequency control signal (vci) from at least one frequency control module; and an output for providing at least one compensation signal (vct) to the controllable oscillator. The at least one compensation module is arranged to compare the at least indication of the frequency control signal (vci) with a reference voltage signal (vref); and generate the at least one compensation signal (vct) based at least partly on the comparison of the indication of the frequency control signal (vci) to the reference voltage signal (vref).

### CROSS REFERENCE TO RELATED APPLICATIONS

This application claims the benefit of U.S. provisional application No. 61/386,885, filed on Sep. 27, 2010 and incorporated herein by reference.

### BACKGROUND OF THE INVENTION

1. Field of the Invention

The field of this invention relates to an integrated circuit device, an electronic device and a method for compensating frequency drift of a controllable oscillator. The invention is applicable to, but not limited to, a method for compensating for frequency drift of a controlled oscillator.

2. Description of the Prior Art

Wireless communication systems, such as the 3^{rd} Generation (3G) of mobile telephone standards and technology, are well known. An example of such 3G standards and technology is the Universal Mobile Telecommunications System (UMTS), developed by the 3rd Generation Partnership Project (3GPP) (www.3gpp.org). The demanding specifications required of a wireless telecommunication handset supporting, for example, a wideband code division multiple access (WCDMA) air interface, such as may be found within a UMTS network, mean that controllable oscillators, such as synthesiser voltage controlled oscillators (VCOs), within a transceiver of such a handset must have excellent phase noise performance.

However, such wireless telecommunication handsets are required to maintain a call for extremely long times. As a result, their transceiver synthesisers must be capable of maintaining a frequency lock over a wide range of temperatures. VCOs have an inherent frequency drift due to changes in temperature, which is hard to reduce below 40 ppm/degC. If temperature-related frequency drift were to be compensated by way of the main control port of the VCO, for example through a conventional phase locked loop (PLL), the VCO would require a substantial control gain (Kvco). As noise on the control port is converted to VCO phase noise, such a substantial control gain typically results in high VCO phase noise, which is not compatible with the requirement of an excellent phase noise performance, such as is required for a wireless telecommunication handset supporting WCDMA. Generally, it is difficult to implement a wide control range without also introducing an unacceptable degradation of phase noise performance.

Known solutions to this problem typically comprise a temperature-dependent voltage signal to an auxiliary varactor within the VCO (via an auxiliary control port thereof) to minimize VCO frequency variations caused by changes in temperature. In this manner, the need for the adjustment range of the main control port of the VCO to be sufficiently large to allow for such frequency variations caused by changes in temperature is substantially alleviated. As a result, the VCO may be provided with a significantly reduced control gain (Kvco), reducing the phase noise of the VCO.

However, a problem with such a solution is that the use of an auxiliary varactor with a temperature-dependent voltage signal requires accurate modelling of temperature behaviour, and typically still requires sufficient adjustment range within the main control port of the VCO to allow sufficient margin for error. Additionally, it is difficult to generate a temperature-dependent voltage in such a manner that the voltage has low noise. Such a solution typically requires significant filtering of the temperature-dependent control voltage in order to reduce phase noise to acceptable levels.

Thus, a need exists for an improved apparatus for compensating for frequency drift within a controlled oscillator, and method of operation therefor.

### SUMMARY OF THE INVENTION

Accordingly, the invention seeks to mitigate, alleviate or eliminate one or more of the above mentioned disadvantages singly or in any combination. Aspects of the invention provide a method for compensating for frequency drift within a controlled oscillator, an integrated circuit device, frequency signal generation circuitry, and an electronic device comprising such frequency signal generation circuitry.

According to a first aspect of the invention, there is provided an integrated circuit device comprising for compensating frequency drift of a controllable oscillator. The integrated circuit device comprises at least one compensation module comprising an input for receiving at least an indication of a frequency control signal (vci) from at least one frequency control module; and an output for providing at least one compensation signal (vct) to the controllable oscillator. The at least one compensation module is arranged to compare the at least indication of the frequency control signal (vci) with a reference voltage signal (vref); and generate the at least one compensation signal (vct) based at least partly on the comparison of the indication of the frequency control signal (vci) to the reference voltage signal (vref).

Thus, in one example embodiment of the invention, by comparing (at least an indication of) the frequency control signal (vci) provided to the first control port of the controllable oscillator with a reference voltage signal (vref), any variation between the frequency control signal (vci) and the reference voltage signal (vref) can be detected, and the at least one compensation signal (vct) set accordingly. In this manner, the at least one compensation signal (vct) may effectively compensate for any frequency drift within the controllable oscillator by maintaining the frequency control signal (vci) at a generally consistent voltage level. Significantly, for some example embodiments of the present invention, the generation of the compensation signal (vct) is not temperature-dependent, and, as such, the compensation module is capable of compensating substantially for any mid-/long- term frequency changes of the controllable oscillator, and not just frequency drift resulting from temperature variations. Furthermore, the compensation module may be relatively simple to implement, thereby placing substantially no demand on modelling of detailed temperature-dependent behaviour, and allowing for a simple and well defined interaction with the frequency control module.

According to an optional feature of the invention, the integrated circuit device may comprise or be operably couplable to the controllable oscillator, wherein the controllable oscillator may comprise a first control port and at least one further control port. According to an optional feature of the invention, the integrated circuit device may comprise or be operably couplable to the at least one frequency control module wherein the at least one frequency control module may comprise a first feedback loop between an output of the controllable oscillator and the first control port thereof.

According to an optional feature of the invention, the at least one compensation module may comprise a second feedback loop between the first control port of the controllable oscillator and the at least one further control port thereof. Additionally, the compensation module may be arranged such that the second feedback loop comprises a bandwidth lower than, and in particular for some examples of the invention significantly lower than, a bandwidth of the first feedback loop. In this manner, any control signal changes applied to the at least one further control port of the controllable oscillator by the compensation module, in order to maintain the frequency control signal (vci) at a generally consistent voltage level, will be at a slower rate, and in particular for some examples of the invention significantly slower rate, than changes applied by the frequency control module to the frequency control signal (vci). Accordingly, the ability of the frequency control module to control the frequency of the frequency signal (fo) output by the controllable oscillator may not be compromised.

According to an optional feature of the invention, the at least one compensation module may comprise a comparison component arranged to receive at a first input thereof the indication of the frequency control signal (vci) and at a second input the reference voltage signal (vref), and to generate at an output thereof the compensation signal (vct) based at least partly on a comparison of the indication of the frequency control signal (vci) with the reference voltage signal (vref). For example, the comparison component may comprise an error transconductance amplifier, and the compensation module may further comprise an integration capacitor operably coupled between the output of the comparison component and a supply voltage of the controllable oscillator. In this manner, a low bandwidth and low phase noise may be achieved for the compensation module and at least one further control port of the controllable oscillator.

Alternatively, the comparison component may comprise an operational amplifier arranged to receive at a non-inverting input thereof, for example via a series resistor, the indication of the frequency control signal (vci) and at an inverting input thereof the reference voltage signal (vref). The operational amplifier may then generate at an output thereof the compensation signal (vct), and the compensation module may further comprise an active RC filter arranged by coupling the output of the operation amplifier to the non-inverting input thereof, for example via a feedback capacitor. In this manner, a low bandwidth and low phase noise may be achieved for the compensation module(s) and at least one further control port of the controllable oscillator.

Alternatively still, the at least one compensation module may further comprise an integrator, an input of which being operably coupled to the output of the comparison component, a delta-sigma modulator, an input of which being operably coupled to an output of the integrator, a digital-to-analogue converter (DAC), an input of which being operably coupled to an output of the delta-sigma modulator, and a low pass filter, an input of which being operably coupled to an output of the DAC. An output of the low pass filter may be operably coupled to the at least one further control port of the at least one controllable oscillator and arranged to provide the at least one compensation signal (vct) thereto. In this manner, a low bandwidth and low phase noise may be achieved for the compensation module and at least one further control port of the controllable oscillator.

According to some optional features of the invention, the compensation module may further comprise calibration circuitry arranged to generate a temperature-dependent calibration signal (vctcal). The compensation module may be arranged to selectively operate in a first configuration in which the compensation module is arranged to output a compensation signal (vct) primarily based on the comparison of the at least indication of the frequency control signal (vci) to the reference voltage signal (vref), and to selectively operate in a second configuration in which the compensation module is arranged to output a compensation signal (vct) based at least partly on the temperature-dependent calibration signal (vctcal). For example, the calibration circuitry may comprise a temperature sensor component arranged to generate a temperature-dependent signal (vtsens), and an enabling component arranged to receive at an input thereof the temperature-dependent signal (vtsens) generated by the temperature sensor component. The calibration circuitry may then selectively offset the compensation signal (vct) in order to generate a temperature-dependent calibration signal (vctcal) based at least partly on the temperature-dependent signal (vtsens) generated by the temperature sensor component. In this manner, if calibration of the controllable oscillator is performed at, say, a temperature extreme limit, such a temperature extreme limit will be taken into account within the calibration signal (vctcal) during the calibration of the controllable oscillator. As a result, a problem of the controllable oscillator being calibrated with the compensation signal (vct) being centred within the tuning curve (Kt) for the at least one further port for such a temperature extreme limit may be substantially alleviated.

According to some optional features of the invention, the at least one compensation module may comprise a comparison component arranged to receive at a first input thereof the indication of the frequency control signal (vci) and at a second input the reference voltage signal (vref), and to selectively output as the compensation signal (vct) the result of a comparison of the indication of the frequency control signal (vci) with the reference voltage signal (vref). In one example, the compensation signal (vct) may be grounded if the temperature calibration loop (TCL) is disabled In this manner, the compensation component may be effectively disabled.

According to some optional features of the invention, the controllable oscillator may comprise at least one from a group consisting of: a voltage controlled oscillator, a current controlled oscillator, a digital controlled oscillator.

According to a second aspect of the invention, there is provided an electronic device comprising at least one controllable oscillator comprising a first control port and at least one further control port and at least one frequency control module comprising an output operably coupled to the first control port of the at least one controllable oscillator and arranged to provide a frequency control signal (vci) thereto. At least one compensation module comprises an output operably coupleable to the at least one further control port of the at least one controllable oscillator and arranged to provide at least one compensation signal (vct) thereto. The at least one compensation module is arranged to receive at least an indication of a frequency control signal (vci) output by the at least one frequency control module; compare the at least indication of the frequency control signal (vci) with a reference voltage signal (vref); and generate the at least one compensation signal (vct) based at least partly on the comparison of the indication of the frequency control signal (vci) to the reference voltage signal (vref)).

According to a third aspect of the present invention, there is provided a method for compensating for frequency drift of a controllable oscillator. The method comprises receiving a frequency control signal (vci) provided to a first control port of the controllable oscillator, comparing the frequency control signal (vci) with a reference voltage signal (vref), generating at least one compensation signal (vct) based at least partly on the comparison of the frequency control signal (vci) with the reference voltage signal (vref), and providing the at least one compensation signal (vct) to at least one further control port of the controllable oscillator.

According to an optional feature of the invention, the method may further comprise, during calibration of the controllable oscillator, applying a compensation signal (vct) based at least partly on a temperature-dependent signal to the at least one further control port of the controllable oscillator.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Further details, aspects and embodiments of the invention will be described, by way of example only, with reference to the drawings. Elements in the figures are illustrated for simplicity and clarity and have not necessarily been drawn to scale. Like reference numerals have been included in the respective drawings to ease understanding.

FIG. 1 illustrates an example of a simplified block diagram of part of an electronic device adapted to support the inventive concepts of an example of the present invention.

FIG. 2 illustrates a simplified example of a VCO circuit which may be used to implement a VCO shown in FIG. 1.

FIG. 3 illustrates an example of a frequency signal generation circuitry according to some embodiments of the present invention.

FIG. 4 and FIG. 5 illustrate further examples of frequency signal generation circuitry according to some alternative embodiments of the present invention.

FIG. 6 and FIG. 7 illustrate simplified flowcharts of an example of a method for compensating for frequency drift within a VCO according to some embodiments of the present invention.

### DETAILED DESCRIPTION

The present invention will now be described with reference to the compensation of a controllable oscillator, for example in a form of a voltage controlled oscillator (VCO) for use within a transceiver of a wireless communication unit, for example as may be adapted to support a wideband code division multiple access (WCDMA) air interface such as may be found within a UMTS™ (Universal Mobile Telecommunications System) network. However, it will be appreciated that the inventive concept described herein is not limited to use for a VCO, and may equally be implemented within any alternative controllable oscillator or application or device comprising controllable oscillator in which compensation for frequency drift is desirable/required, for example a current controlled oscillator, a digital controlled oscillator or any hybrid combination.

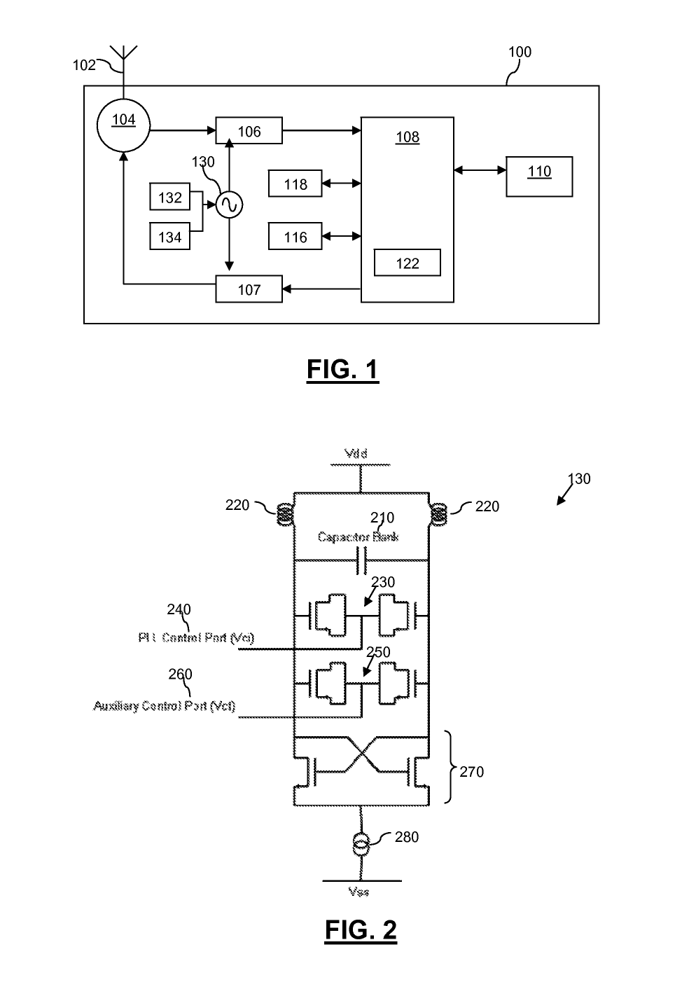

Referring first to FIG. 1, there is illustrated an example of a simplified block diagram of part of an electronic device 100 adapted to support the inventive concept of an example of the present invention. The electronic device 100, in the context of the illustrated embodiment of the invention, is a wireless telecommunication handset. As such, the electronic device 100 comprises an antenna 102 and contains a variety of well known radio frequency transceiver components or circuits operably coupled to the antenna 102. In particular for the illustrated example, the antenna 102 is operably coupled to a duplex filter or antenna switch 104 that provides isolation between a receiver chain 106 and a transmitter chain 107. As is known in the art, the receiver chain 106 typically includes radio frequency receiver circuitry for providing reception, filtering and intermediate or base-band frequency conversion. Conversely, the transmitter chain 107 typically includes radio frequency transmitter circuitry for providing modulation and power amplification.

For completeness, the electronic device 100 further comprises signal processing logic 108. An output from the signal processing logic 108 may be provided to a suitable user interface (UI) 110 comprising, for example, a display, keypad, microphone, speaker, etc. The signal processing logic 108 may also be coupled to a memory element 116 that stores operating regimes, such as decoding/encoding functions and the like and may be realised in a variety of technologies such as (volatile) random access memory (RAM), (non-volatile) read only memory (ROM), Flash memory or any combination of these or other memory technologies. A timer 118 is typically coupled to the signal processing logic 108 to control the timing of operations within the electronic device 100.

As is well known in the art, the transmitter and receiver chains of such a wireless telecommunication handset require accurate frequency signals in order to correctly perform their required functions. Typically, such frequency signals are provided by way of one or more VCOs, illustrated generally at 130. Such a VCO 130 is arranged to output a defined frequency signal, which may subsequently be modified (e.g. phase shifted and or frequency multiplied/divided) as required for use by the respective transmitter/receiver chain 107/106. As previously mentioned, the demanding specifications required of such wireless telecommunication handsets mean that such VCOs within a transceiver of such a wireless handset must have excellent phase noise performance, whilst being able to maintain a call indefinitely. As a result, their transceiver synthesisers must be capable of maintaining a frequency lock under various conditions, including over a wide range of temperatures.

Thus, the electronic device (e.g., the wireless telecommunication handset) 100 of FIG. 1 comprises at least one frequency control module, illustrated generally at 132, arranged to provide a frequency control signal to a first (main) control port of the VCO 130 in order to maintain a required frequency lock of the signal output by the VCO 130. The electronic device (e.g., the wireless telecommunication handset) 100 of FIG. 1 further comprises at least one compensation module, illustrated generally at 134, arranged to provide at least one compensation signal to at least one further (auxiliary) control port of the VCO 130.

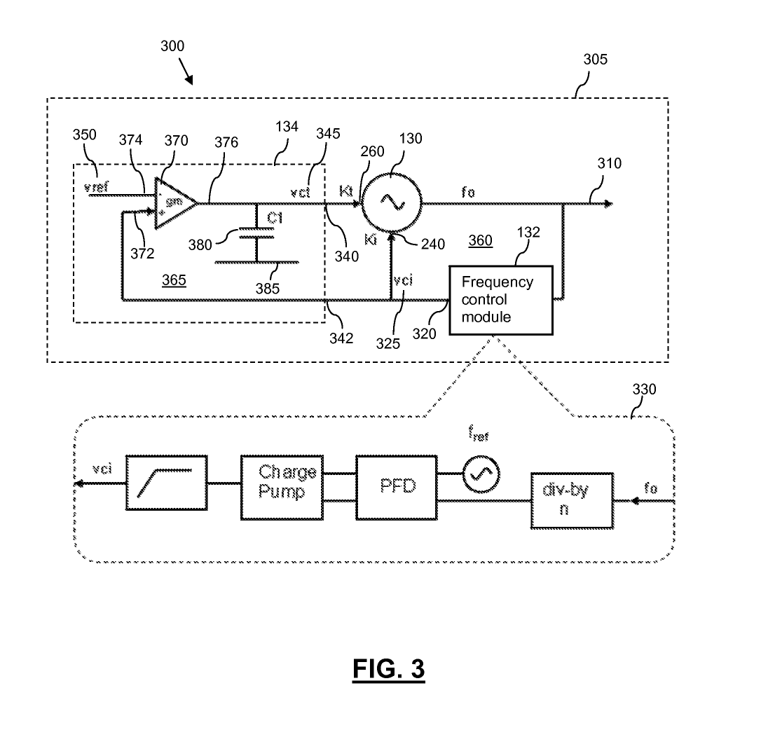

FIG. 2 illustrates a simplified example of a VCO circuit, such as may be used to implement the, or each, VCO 130 of the electronic device (e.g., the wireless telecommunication handset) 100 of FIG. 1. The VCO 130 comprises an LC (inductance/capacitance) tank circuit, which for the illustrated example comprises a capacitor bank, illustrated generally at 210, and an inductance circuit, illustrated generally by inductances 220. The LC tank circuit acts as a resonant circuit which generates an oscillating signal at the resonant frequency of the resonant circuit. As is known, by providing one or more varactors within the resonant circuit of the VCO 130, the resonant frequency of the resonant circuit may be varied, thereby varying the frequency of the oscillating signal generated thereby.

Accordingly for the illustrated example, a first varactor 230, comprising a voltage controlled capacitance in this example, is operably coupled in parallel with the capacitor bank 210, and thereby arranged to enable the capacitance of the LC tank circuit to be controllably varied. A control terminal of this first varactor 230 is arranged to provide a first, ‘main’ control port 240 for the VCO 130, for example to which the frequency control module 132 of FIG. 1 may be operably coupled. In this manner, a control signal received at the first, main control port 240 of the VCO 130 may be used to at least partially control a resonant frequency of the resonant circuit of the VCO 130, for example to maintain a desired output frequency of the VCO 130 by way of, for example, a phase locked loop (PLL).

One or more further, auxiliary, varactors may be provided within the resonant circuit of the VCO 130 to enable further manipulation of the resonant frequency of the resonant circuit of the VCO 130, for example to enable frequency drift of the resonant circuit due to, say, changes in temperature or the like, to be compensated for. Accordingly, the VCO 130 illustrated in FIG. 2 comprises a further, auxiliary varactor 250, again comprising a voltage controlled capacitance in this example, which is also operably coupled in parallel with the capacitor bank 210, and thereby arranged to enable the capacitance of the LC tank circuit to be further controllably varied. A control terminal of this auxiliary varactor 250 is arranged to provide a further, ‘auxiliary’ control port 260 of the VCO 130, for example to which the compensation module 134 of FIG. 1 may be operably coupled. In this manner, a control signal received at the further, auxiliary control port 260 of the VCO 130 may be used to further control the resonant frequency of the resonant circuit of the VCO 130, for example to compensate for frequency drift due to, say, changes in temperature or the like.

In one example, by enabling frequency drift to be compensated for outside of a main frequency control loop, for example provided by a PLL coupled to the main control port 240 of the VCO 130, the control gain required for the main control port 240 is not required to be excessively large in order to compensate for such frequency drift, thereby enabling low VCO phase noise to be achieved through the main control port 240.

For completeness, the VCO 130 also comprises an amplifier stage, indicated generally at 270, for providing an adequate gain of the oscillating signal generated by the resonant circuit of the VCO 130, and a current sink 280.

In some examples, the main control port 240 may be either an analogue or digital input, dependent upon whether the controllable oscillator is a current controlled oscillator, a digital controlled oscillator or any hybrid combination thereof. Similarly, in some examples, the auxiliary control port 260 may be either an analogue or digital input, dependent upon whether the controllable oscillator is a current controlled oscillator, a digital controlled oscillator or any hybrid combination thereof is desirable/required, for example a current controlled oscillator, a digital controlled oscillator or any hybrid combination. Thus, in this example, there are four possible implementations whereby the main control port 240 may be either an analogue or digital input and the auxiliary control port 260 may also be either an analogue or digital input.

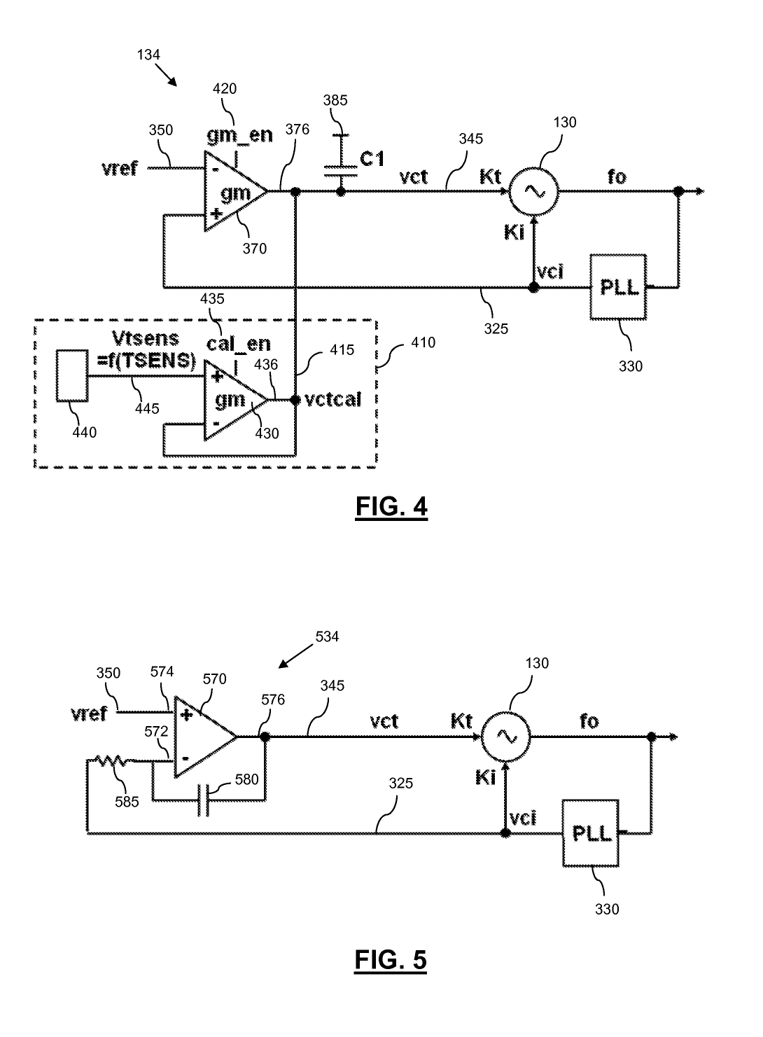

Referring now to FIG. 3, there is illustrated an example of a frequency signal generation circuitry 300 according to some example embodiments of the present invention, the frequency signal generation circuitry 300 being arranged to generate a frequency signal (fo) 310, for example such as may be provided to the transmitter and/or receiver chains 107, 106 of the electronic device (e.g., the wireless telecommunication handset) 100 of FIG. 1. For the illustrated example, the frequency signal generation circuitry 300 is implemented within an integrated circuited device 305. It is contemplated that such integrated circuit device 300 may further comprise some or all of the transmitter and/or receiver chain components of the electronic device (e.g., the wireless telecommunication handset) 100.

In this example, the frequency signal generation circuitry 300 comprises at least one voltage controlled oscillator component (VCO), such as VCO 130 of FIG. 1, comprising a first control port (e.g. main control port 240 illustrated in FIG. 2) and at least one further control port (e.g. auxiliary control port 260 illustrated in FIG. 2). The frequency signal generation circuitry 300 further comprises at least one frequency control module, such as the frequency control module 132 illustrated in FIG. 1, comprising an output 320 operably coupled to the first control port 240 of the VCO 130 and arranged to provide a frequency control signal (vci) 325 thereto. For the example illustrated in FIG. 3, the frequency control module 132 comprises a phase locked loop (PLL), as partially illustrated at 330, arranged to provide a feedback loop between the frequency signal (fo) 310 output by the VCO 130 and the main control port 240 thereof. PLLs are well known in the art and as such the PLL 330 illustrated in FIG. 3 need not be described in any further detail herein.

In this example, the frequency signal generation circuitry 300 further comprises at least one compensation module, such as the compensation module 134 illustrated in FIG. 1. The compensation module 134 comprises an output 340 operably coupled to the at least one further (auxiliary) control port 260 of the VCO 130, and is arranged to provide at least one compensation signal (vct) 345 thereto. The compensation module 134 is arranged to receive at an input 342 thereof an indication of the frequency control signal (vci) 325 output by the frequency control module 132, to compare the indication of the frequency control signal (vci) 325 to a reference voltage signal (vref) 350, and to generate the compensation signal (vct) 345 based at least partly on the comparison of the indication of the frequency control signal (vci) 325 with the reference voltage signal (vref) 350.

By comparing (at least an indication of) the frequency control signal (vci) 325 provided to the main control port 240 of the VCO 130 with a reference voltage signal (vref) 350, any variation between the frequency control signal (vci) 325 and the reference voltage signal (vref) 350 can be detected, and the compensation signal (vct) 345 set or modified accordingly. For example, the compensation signal (vct) 345 may be set to represent a difference between the frequency control signal (vci) 325 and the reference voltage signal (vref) 350. In this manner, the compensation module 134 (and auxiliary varactor 250 of the VCO 130) may be arranged to control the resonant frequency of the resonant circuit within the VCO 130 such that the frequency control signal (vci) 325 output by the frequency control module 132 is maintained at a generally consistent voltage level (relative to the reference voltage signal (vref) 350), for example by maintaining the frequency control signal (vci) 325 generally equal to the reference voltage signal (vref) 350. In this manner, the compensation signal (vct) 345 is able to effectively compensate for any frequency drift within the VCO 130 by maintaining the frequency control signal (vci) 325 at a generally consistent voltage level, for example at a voltage level generally centred within the tuning curve for the main control port 240 of the VCO 130.

In this manner, the frequency control signal (vci) 325 is not required to compensate for frequency drift within the VCO 130, and as a result the main control port 240 and respective varactor 230 are not required to provide a large control gain (Ki), thereby enabling a low phase noise to be achieved within the main control loop comprising the frequency control module 132. The reference voltage signal (vref) 350 may be selected to be any suitable value, and effectively determines a voltage level at which the frequency control signal (vci) 325 will generally be maintained at. Thus, for example, the reference voltage signal (vref) 350 may be selected such that the frequency control signal (vci) 325 may be generally maintained around a calibration voltage used during VCO sub-band selection (typically at or near a peak of the control gain (Kvco) curve for the VCO 130).

For the example illustrated in FIG. 3, the compensation signal (vct) 345 is generated based on a substantially direct comparison of the frequency control signal (vci) 325 provided to the main control port 240 of the VCO 130 and the reference voltage signal (vref) 350. However, in some examples the compensation signal (vct) 345 may equally be generated based on a comparison of an ‘indication’ of the frequency control signal (vci) 325 with the reference voltage signal (vref) 350. For example, the compensation signal (vct) 345 may be generated based on a comparison of a fraction (1/n) of the frequency control signal (vci) 325 (e.g. provided by way of a voltage divider circuit or the like). In this manner, the frequency control signal (vci) 325 may be generally maintained at a voltage substantially equal to n*vref.

As illustrated in FIG. 3, the frequency control module 132 comprises a first feedback loop 360 (in a form of a PLL for the illustrated example) between the output 310 of the VCO 130 and the first, main control port 240 thereof. In addition, for the illustrated example the compensation module 134 comprises a second feedback loop 365 between the first, main control port 240 of the VCO 130 and the second, auxiliary control port 260 thereof. In effect, this second feedback loop 365 of the compensation module 134 provides an extension to the first feedback loop 360 of the frequency control module 132. In some examples, the compensation module 134 may be arranged such that the second feedback loop 365 comprises a bandwidth lower than a bandwidth of the first feedback loop 360. In this manner, any control signal changes applied to the auxiliary control port 260 of the VCO 130 by the compensation module 134, in order to maintain the frequency control signal (vci) 325 at a generally consistent voltage level, will be at a slower rate than changes applied by the frequency control module 132 to the frequency control signal (vci) 325. Accordingly, the ability of the frequency control module 132 to control the frequency of the frequency signal (fo) 310 output by the VCO 130 is not compromised.

For example, a temperature change +dT may cause a frequency drift within the VCO 130 of −a.dT, resulting in a corresponding change in the frequency of the frequency signal (fo) 310 output by the VCO 130. In response to such a change in the frequency of the frequency signal (fo) 310, the frequency control module 132 is arranged to increase the voltage of the frequency control signal (vci) 325 by +dF/Ki in order to correct the frequency of the frequency signal (fo) 310. In response to such a change in the frequency of the frequency control signal (vci) 325, the compensation module 134 increases (at a slower rate) the voltage of the compensation signal (vct) 345 by +dF/Kt, thereby causing the voltage of the frequency control signal (vci) 325 to be returned to its original level (e.g. equal to that of the reference voltage signal (vref) 350). Since the bandwidth of the second feedback loop 365 is lower than that of the first feedback loop 360, the frequency control module 132 is able to substantially maintain the frequency of the frequency signal (fo) 310 at the desired frequency, whilst the compensation module 134 causes the voltage of the frequency control signal (vci) 325 to be returned to its original level.

In particular, in some examples the compensation module 134 may be arranged such that the second feedback loop 365 comprises a bandwidth significantly lower than the bandwidth of the first feedback loop 360 (for example the second feedback loop 365 having a bandwidth of less than 1 kHz as compared with, say, a bandwidth of 100 kHz for the first feedback loop 360). In this manner, the loop dynamics of the frequency control module 132 will not be significantly affected, thereby enabling low phase noise levels and fast lock times to be perceived at the output (f0) 310 of the VCO 130.

It is contemplated that for some example embodiments of the present invention, the compensation module 134 may be designed to compensate for, say, temperature-induced changes within the VCO 130. Accordingly, a time constant of approximately 1 ms (millisecond) or more may be sufficient to track such changes. Although localised heating due to, for example, on-chip power consumption may cause faster changes, the frequency control module 132 is typically capable of correcting for these in the short term, with the compensation module 132 eventually providing the necessary compensation thereafter.

For the example illustrated in FIG. 3, the compensation module 134 comprises a comparison component, logic or module, which for the illustrated example is in a form of an error transconductance amplifier, 370 arranged to receive at a first input 372 thereof the frequency control signal (vci) 325 and at a second input 374 the reference voltage signal (vref) 350. The error transconductance amplifier 370 generates the compensation signal (vct) 345 at an output 376 based at least partly on a comparison of the frequency control signal (vci) 325 with the reference voltage signal (vref) 350. The compensation module 134 further comprises an integration capacitor 380 operably coupled between the output 376 of the error transconductance amplifier (e.g., the comparison component) 370 and a supply voltage 385, such as provided by way of a positive or negative voltage supply rail or a ground rail, of the integrated circuit device 305. In this manner, the bandwidth of the compensation module 134 may be defined as gm/(2πC1), where C1 represents a capacitance of the integration capacitor 380, and gm represents a transconductance value for the error transconductance amplifier 370.

The generation of the compensation signal (vct) 345 for the illustrated example is not temperature-dependent, and as such the compensation module 134 is capable of compensating for substantially any mid-/long-term frequency changes of the VCO 130, and not just frequency drift resulting from temperature variations. Advantageously, the illustrated example of the present invention enables a wide compensation range to be achieved with negligible effect on phase noise performance for the VCO 130. Furthermore, the compensation module 134 of the illustrated example is relatively simple to implement, thereby placing substantially no demand on modelling of detailed temperature-dependent behaviour of VCOs, and having a simple and well defined interaction with the frequency control module 132.

During calibration of the VCO 130, for example during sub-band selection for the VCO 130, the compensation signal (vct) 345 may be set to a known calibration value (vctcal). For example, the compensation signal (vct) 345 may be set to a calibration value (vctcal) located substantially at the centre of the tuning curve (Kt) for the auxiliary control port 260 to which it is provided. In this manner, after calibration, with both feedback loops 360, 365 active, the compensation signal (vct) 345=vctcal, whilst the frequency control signal (vci) 325 is approximately equal to vcical, where vcical is a value of the frequency control signal (vci) 325 to which the VCO 130 is calibrated. Immediately after calibration, vci may move a small amount away from vcical during PLL locking. This is due to the finite size of the VCO frequency bands. The compensation module 134 of the illustrated example may provide the additional benefit of holding the frequency control signal (vci) 325 generally around vcical through the adjustment range of the compensation module 134 for any VCO band. In this manner, the compensation module 134 may reduce the observed variation in the control gain (Ki) for the main control port 240 of the VCO 130, and the overall loop gain of the frequency control module 132. If the total adjustment range for the auxiliary control port 260 of the VCO 130 is frange, setting the compensation signal (vct) 345 to a calibration value (vctcal) located substantially at the centre of the tuning curve (Kt) for the auxiliary control port 260 will allow approximately symmetric adjustment by the compensation module 134 of +/−frange/2.

However, if such calibration is performed at, say, a temperature extreme limit, such calibration will result in the VCO 130 being calibrated with the compensation signal (vct) 345 being centred within the tuning curve (Kt) for the auxiliary control port 260 for that temperature extreme limit. Accordingly, only approximately half the adjustment range will be useful, since the remainder of the adjustment range will be beyond the temperature extreme limit. Thus, in some example embodiments of the present invention the value to which the compensation signal (vct) 345 is set during calibration of the VCO 130 is made/selected as a function of temperature.

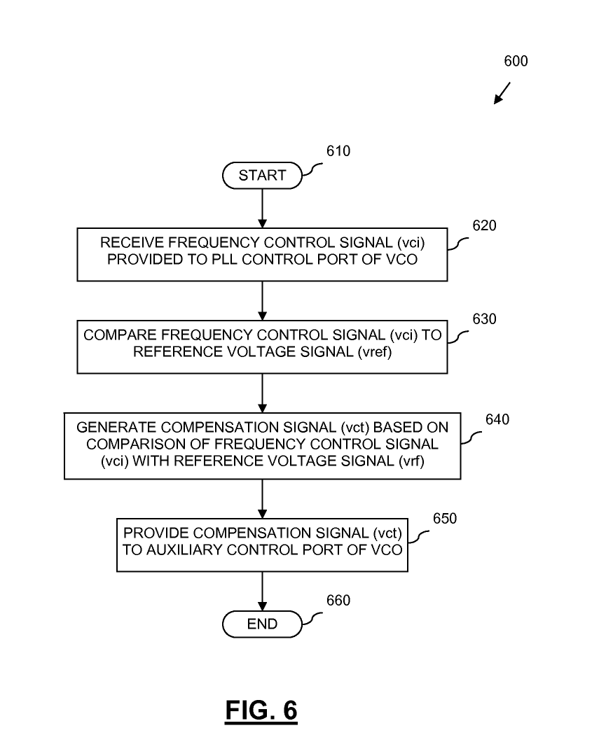

FIG. 4 illustrates such an example of the compensation module 134 according to some alternative example embodiments of the present invention in which the compensation module 134 comprises calibration circuitry 410 arranged to generate a temperature-dependent calibration signal (vctcal) 415. Accordingly, the compensation module 134 of FIG. 4 is arranged to selectively operate, in a first (compensation) configuration in which the compensation module 134 is arranged to output a compensation signal (vct) 345 primarily based on the comparison of the (indication of the) frequency control signal (vci) 325 with the reference voltage signal (vref) 350. The compensation module 134 is further arranged to selectively operate in a second (calibration) configuration in which the compensation module 134 is arranged to output a compensation signal (vct) 345 based at least partly on the temperature-dependent calibration signal (vctcal) 415.

For example, the calibration circuitry 410 may comprise an enabling component, which for the illustrated example comprises an error transconductance amplifier 430 arranged to receive at a first (non-inverting) input thereof a temperature-dependent signal Vtsens 445, which for the illustrated example is provided by a temperature sensor 440. An output 436 of the error transconductance amplifier 430 is looped back to an inverting input of the error transconductance amplifier 430. The output 436 of the error transconductance amplifier 430 of the calibration circuitry 410 is further operably coupled to the output 376 of the error transconductance amplifier 370. The error transconductance amplifier 430 of the calibration circuitry 410 is further arranged to receive an enable signal (cal_en) 435. In this manner, the error transconductance amplifier 430 of the calibration circuitry 410 may selectively (i.e. depending on the enable signal (cal_en) 435) over-ride the signal output by error transconductance amplifier 370 based on the temperature-dependent signal Vtsens 445 to generate the temperature-dependent calibration signal (vctcal) 415.

Thus, for the illustrated example, when the compensation module 134 is selectively arranged, by way of the enable signal (cal_en) 435 being set to ‘disable’ the error transconductance amplifier 430 of the calibration circuitry 410, in order to operate in the first (compensation) configuration, the compensation signal (vct) 345 is substantially based on the comparison of the (indication of the) frequency control signal (vci) 325 to the reference voltage signal (vref) 350 by the error transconductance amplifier 370. Conversely, when the compensation module 134 is selectively arranged, by way of the enable signal (cal_en) 435 being set to ‘enable’ the error transconductance amplifier 430 of the calibration circuitry 410, in order to operate in the second (calibration) configuration, the compensation signal (vct) 345 is substantially based on a temperature-dependent voltage (vctcal) 415 provided by the calibration circuitry 410. Thus, in this manner, by enabling the calibration circuitry 410, the compensation signal (vct) 345 comprises the temperature-dependent calibration signal (vctcal) 415. As a result, during calibration of the VCO 130, the compensation module 134 may be selectively configured to apply a calibration signal (vctcal), based at least partly on a temperature-dependent signal to the at least one further control port of the VCO. In this manner, if such calibration is performed at, say, a temperature extreme limit, such a temperature extreme limit will be taken into account within the calibration signal (vctcal) during the calibration of the VCO 130. As a result, the problem of the VCO 130 being calibrated with the compensation signal (vct) 345 being centred within the tuning curve (Kt) for the auxiliary port 260 for such a temperature extreme limit may be substantially alleviated.

For the illustrated example, the error transconductance amplifier 370 of the compensation module 134 is also arranged to receive an enable signal (gm_en) 420. In this manner, the error transconductance amplifier 370 may selectively output as the compensation signal (vct) 345 the result of a comparison of the indication of the frequency control signal (vci) 325 with the reference voltage signal (vref), based on the enable signal (gm_en) 420. Thus, the compensation module 134 may be disabled.

The compensation module 134 illustrated in FIG's 3 and 4 comprises a low transconductance stage comprising the error transconductance amplifier 370 and integration capacitor 380 to achieve a desired low bandwidth and low noise for the feedback loop 365. FIG. 5 illustrates an example of a compensation module 534 according to some alternative example embodiments of the present invention, in which the desired low bandwidth and low noise for the second feedback loop 365 is achieved by an alternative means. Specifically for the example illustrated in FIG. 5, the compensation module 534 comprises a comparison component in a form of an operational amplifier 570 arranged to receive at a inverting input 572 thereof the indication of the frequency control signal (vci) 325 and at a non-inverting input 574 thereof the reference voltage signal (vref) 350, and to generate at an output 576 thereof the compensation signal (vct) 345. The compensation module 534 further comprises an active resistor-capacitor (RC) filter, which for the illustrated example comprises capacitor 580 and resistor 585, arranged to couple the output 576 of the operation amplifier 570 to the inverting input 572 thereof. As will be appreciated by a skilled person, a positive gain (Kvco) has been assumed for the main control port 240 and the auxiliary control port 260 of the VCO 130 in the examples illustrated in FIGS. 3 and 4. However, for the example illustrated in FIG. 5, the auxiliary control port would require a negative gain. Although not illustrated, the compensation module 534 illustrated in FIG. 5 may also comprise calibration circuitry comparable to that of the embodiment illustrated in FIG. 4.

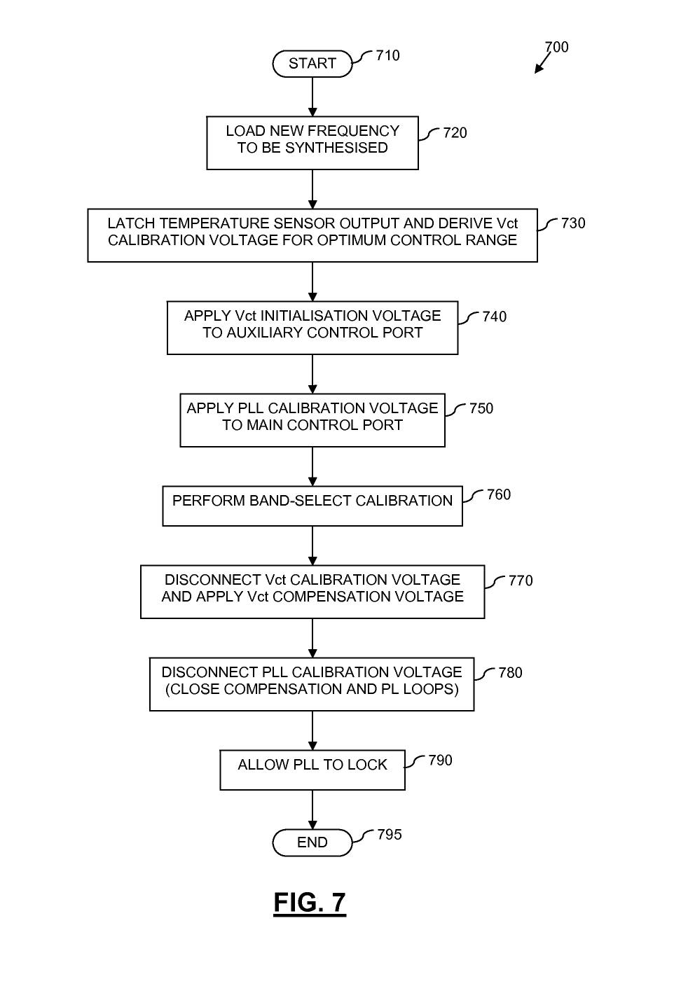

Referring now to FIG's 6 and 7 there are illustrated simplified flowcharts 600, 700 of an example of a method for compensating for frequency drift within a VCO, for example due to temperature variations, etc., according to some example embodiments of the present invention. Referring first to FIG. 6, there is illustrated a flowchart 600 of a first (compensation) part of the method, such as may be implemented by the frequency signal generation circuit 300 illustrated in FIGS. 3 to 5. This first part of the method starts at step 610 and moves on to step 620 where a frequency control signal (e.g. vci 325 in FIGS. 3 to 5) provided to a first (main) control port of the VCO is received. Next, at step 630, the received frequency control signal (vci) is compared to a reference voltage signal (e.g. vref 350 in FIG's 3 to 5). A compensation signal (e.g. vct 345 in FIGS. 3 to 5) is then generated at step 640 based at least partly on the comparison of the frequency control signal (vci) to a reference voltage signal (vref). The compensation signal (vct) is then provided to a further (auxiliary) control port of the VCO, at step 650, and this part of the method then ends at step 660.

Referring now to FIG. 7, there is illustrated a flowchart 700 of a second (calibration) part of the method, such as may also be implemented by the frequency signal generation circuit 300 illustrated in FIGS. 3 to 5, for example where a compensation module 134, 534 of said frequency signal generation circuit 300 comprises calibration circuitry, such as the calibration circuitry 410 illustrated in FIG. 4. This second part of the method starts at step 710, for example with an initialisation of a VCO calibration (sub-band selection) procedure, and moves on to step 720 where one or more parameters for a required new frequency to be synthesized is/are loaded, for example into a fractional-N divider and reference frequency source for the PLL 330 illustrated in FIG. 3. Next, at step 730, a temperature sensor output comprising a temperature-dependent signal is latched, and a calibration signal (vctcal) is derived based at least partly on the temperature-dependent signal (for example as hereinbefore described with reference to FIG. 4). The derived calibration signal is then applied to the further (auxiliary) control port of the VCO at step 740. A calibration voltage is then applied to the first (main) control port of the VCO, at step 750, and band selection calibration is then performed for the VCO at step 760. Such band selection calibration of VCOs is known in the art, and as such need not be described in greater detail herein. However, for reference, an example of such band selection calibration of VCOs is described in A Kral, F Behbahanin and A A Abidi, “RF CMOS Oscillators with switched tuning”. Proc. IEEE Custom Integrated Circuits Conf. Santa Clara, Calif., 1998. pp555-558. S Brett, J Strange, P Fowers, C Jones “Voltage Controlled Oscillator having improved phase noise” U.S. Pat. No. 7,038,552, which is incorporated by reference herein in its entirety.

Having performed the band selection calibration for the VCO, a compensation control signal (vct) based at least partly on a comparison of a control signal applied to the main control port of the VCO to a reference voltage signal (vref) (for example as generated in step 640 of FIG. 6) is then applied to the further (auxiliary) control port of the VCO at step 770, in place of the calibration signal (vctcal). The calibration voltage applied to the main control port of the VCO is then disconnect and replaced with a frequency control signal (vci) provided by way of, for the illustrated example, a PLL at step 780. The PLL is then allowed to lock, at step 790, before the method ends at step 795. As will be appreciated by a skilled person, the various method steps illustrated in FIG. 7, and hereinbefore described, are not limited to being performed in the illustrated and described order, and it is contemplated that several of the steps may be performed in a different order without significantly affecting the outcome of the method. For example, it is contemplated that the order of steps 740 and 750 may be reversed. Equally, it is contemplated that the order of steps 770 and 780 may be reversed.

The illustrated example embodiments of the present invention have, for the most part, been implemented using electronic components and circuits known to those skilled in the art. Accordingly, details have not been explained in any greater extent than that considered necessary as illustrated above, for the understanding and appreciation of the underlying concepts of the present invention and in order not to obfuscate or distract from the teachings of the present invention.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, a plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediary components. Likewise, any two components so associated can also be viewed as being “operably connected”, or “operably coupled”, to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an”, as used herein, are defined as one or more than one. Also, the use of introductory phrases such as “at least one” and “one or more” in the claims should not be construed to imply that the introduction of another claim element by the indefinite articles “a” or “an”, limits any particular claim containing such introduced claim element to inventions containing only one such element, even when the same claim includes the introductory phrases “one or more” or “at least one” and indefinite articles such as “a” or “an”. The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit device for compensating frequency drift of a controllable oscillator, wherein the integrated circuit device comprises:
at least one compensation module comprising:
an input for receiving at least an indication of a frequency control signal (vci) from at least one frequency control module; and
an output for providing at least one compensation signal (vct) to the controllable oscillator;
wherein the at least one compensation module is arranged to:
compare the at least indication of the frequency control signal (vci) with a reference voltage signal (vref); and
generate the at least one compensation signal (vct) based at least partly on the comparison of the indication of the frequency control signal (vci) to the reference voltage signal (vref).

2. The integrated circuit device of claim 1 wherein the integrated circuit device comprises or is operably couplable to the controllable oscillator wherein the controllable oscillator comprises a first control port and at least one further control port.

3. The integrated circuit device of claim 2 wherein the integrated circuit device comprises or is operably couplable to the at least one frequency control module wherein the at least one frequency control module comprises a first feedback loop between an output of the controllable oscillator and the first control port thereof.

4. The integrated circuit device of claim 3 wherein the at least one compensation module comprises a second feedback loop between the first control port of the controllable oscillator and the at least one further control port thereof; the at least one compensation module being arranged such that the second feedback loop comprises a bandwidth lower than a bandwidth of the first feedback loop.

5. The integrated circuit device of claim 1 wherein the at least one compensation module comprises a comparison component arranged to receive at a first input thereof the indication of the frequency control signal (vci).

6. The integrated circuit device of claim 5 wherein, the reference voltage signal (vref) is received at a second input of the comparison component.

7. The integrated circuit device of claim 6 wherein the at least one compensation module is further arranged to generate at an output thereof a compensation signal (vct) based at least partly on a comparison of the at least indication of the frequency control signal (vci) with the reference voltage signal (vref).

8. The integrated circuit device of claim 7 wherein the comparison component further comprises an error transconductance amplifier and the at least one compensation module further comprises an integration capacitor operably coupled between the output of the comparison component and a supply voltage of the controllable oscillator.

9. The integrated circuit device of claim 7 wherein the comparison component further comprises an operational amplifier arranged to receive at an inverting input thereof the indication of the frequency control signal (vci) and at a non-inverting input thereof the reference voltage signal (vref).

10. The integrated circuit device of claim 9 wherein the compensation module is further arranged to generate at an output thereof the compensation signal (vct); and wherein the compensation module further comprises an active RC filter arranged by coupling an output of the operation amplifier to the inverting input thereof.

11. The integrated circuit device of claim 1 wherein the at least one compensation module further comprises calibration circuitry arranged to generate a temperature-dependent calibration signal (vctcal).

12. The integrated circuit device of claim 11 wherein the at least one compensation module is further arranged to:
selectively operate in a first configuration in which the compensation module is arranged to output a compensation signal (vct) primarily based on the comparison of the at least indication of the frequency control signal (vci) with the reference voltage signal (vref); and
selectively operate in a second configuration in which the compensation module is arranged to output a compensation signal (vct) based at least partly on the temperature-dependent calibration signal (vctcal).

13. integrated circuit device of claim 11 wherein the calibration circuitry further comprises a temperature sensor component arranged to generate a temperature-dependent signal (vtsens), and an enabling component arranged to receive at an input thereof the temperature-dependent signal (vtsens) generated by the temperature sensor component.

14. The integrated circuit device of claim 13 wherein the calibration circuitry is further arranged to selectively over-ride the compensation signal (vct) in order to generate a temperature-dependent calibration signal (vctcal) based at least partly on the temperature-dependent signal (vtsens) generated by the temperature sensor component.

15. The integrated circuit device of claim 1 wherein the at least one compensation module comprises a comparison component arranged to receive at a first input thereof the indication of the frequency control signal (vci) and at a second input the reference voltage signal (vref), and to selectively output as the compensation signal (vct) a result of a comparison of the at least indication of the frequency control signal (vci) with the reference voltage signal (vref).

16. The integrated circuit device of claim 1 wherein the controllable oscillator comprises at least one from a group consisting of: a voltage controlled oscillator, a current controlled oscillator, and a digital controlled oscillator.

17. An electronic device comprising:
at least one controllable oscillator comprising a first control port and at least one further control port;
at least one frequency control module comprising an output operably coupled to the first control port of the at least one controllable oscillator and arranged to provide a frequency control signal (vci) thereto; and
at least one compensation module comprising an output operably coupleable to the at least one further control port of the at least one controllable oscillator and arranged to provide at least one compensation signal (vct) thereto,
wherein the at least one compensation module is arranged to:
receive at an input thereof at least an indication of the frequency control signal (vci) output by the at least one frequency control module;
compare the at least indication of the frequency control signal (vci) with a reference voltage signal (vref); and
generate the at least one compensation signal (vct) based at least partly on the comparison of the indication of the frequency control signal (vci) with the reference voltage signal (vref).

18. A method for compensating frequency drift of a controllable oscillator, the method comprising:
receiving a frequency control signal (vci) provided to a first control port of the controllable oscillator;
comparing the frequency control signal (vci) with a reference voltage signal (vref);
generating at least one compensation signal (vct) based at least partly on the comparison of the frequency control signal (vci) with the reference voltage signal (vref); and
providing the at least one compensation signal (vct) to at least one further control port of the controllable oscillator.

19. The method of claim 18 wherein the method further comprises, during calibration of the controllable oscillator, applying a compensation signal (vct) based at least partly on a temperature-dependent signal to the at least one further control port of the controllable oscillator.
